(19) United States
(12) Patent Application Publication
(10) Pub. No.: US 2009/0236608 A1
(43) Pub. Date: Sep. 24, 2009

(54) Method for Producing Graphitic Patterns on Silicon Carbide

(75) Inventors: Walt A. de Heer, Atlanta, GA (US); Phillip N. First, Doraville, GA (US)

Correspondence Address: BRYAN W. BOCKHOP, ESQ.;BOCKHOP & ASSOCIATES, LLC, 2375 MOSSY BRANCH DR., SNELLVILLE, GA, 30078, US

(73) Assignee: GEORGIA TECH RESEARCH CORPORATION, Atlanta, GA (US)

(21) Appl. No.: 12/165,837

(22) Filed: Jul. 1, 2008

Related U.S. Application Data
(60) Provisional application No. 61/037,591, filed on Mar. 18, 2008.

(51) Int. Cl. H01L 21/3065; B32B 3/30; H01L 29/24

(52) U.S. Cl. 257/77; 428/119; 438/712; 257/E21.218; 257/E29.104

(57) ABSTRACT

In a method of making a vertical graphitic path on a silicon carbide crystal having a horizontal surface, a portion of the silicon carbide crystal is removed from the horizontal surface so as to define a vertical surface that is transverse to the horizontal surface of the silicon carbide crystal. The vertical surface is annealed so as to generate a thin-film graphitic layer on the vertical surface. In another method of making graphitic layers, a material that inhibits formation of a graphitic layer when the silicon carbide crystal is annealed is applied to a surface of a silicon carbide crystal so as to define at least one opening that exposes a portion of the surface of the silicon carbide crystal. The portion of the silicon carbide crystal is annealed so as to generate a thin-film graphitic layer in the portion of the silicon carbide crystal.

### CROSS-REFERENCE TO RELATED APPLICATION(S)

This application claims the benefit of U.S. Provisional Patent Application Ser. No. 61/037,591, filed Mar. 18, 2008, the entirety of which is hereby incorporated herein by reference.

### BACKGROUND OF THE INVENTION

1. Field of the Invention

The present invention relates to electronic devices and, more specifically, to electronic devices employing thin-film graphitic layers.

2. Description of the Prior Art

Electronic devices based on interconnected graphitic structures have been proposed as an alternative to silicon based electronics. Methods have been developed to produce and to pattern graphitic material on silicon carbide in order to produce interconnected graphitic structures.

Ultra-thin graphitic layers grow on silicon carbide crystals when they are subjected to a high temperature annealing process, in which the silicon carbide crystal is heated in a vacuum or in other controlled environments to temperatures in the range of 1200° C. to about 1500° C. for about 30 seconds to about 2 hours. At these high temperatures, silicon evaporates from the silicon carbide surface so that the surface becomes carbon rich. This carbon rich surface then converts to an ultra-thin graphitic layer consisting of from one to several hundred graphene sheets. This ultra-thin graphitic layer is also known as multi-layered graphene. Ultra-thin graphitic layers grow more quickly on the carbon terminated face of hexagonal silicon carbide, while they grow more slowly on the silicon terminated face. Under similar growth conditions, the rate of growth on the carbon terminated face is about an order of magnitude greater then on the silicon terminated face.

Ultra-thin graphitic layers can be patterned using microelectronics lithography methods to produce patterned ultra-thin graphitic layers on silicon carbide. For example, an ultra-thin graphitic layer can be patterned by applying a thin coating of poly methyl methacrylate (PMMA), which inhibits growth of graphitic layers during annealing, on an ultra-thin graphitic layer that is subsequently exposed to electron irradiation supplied by an electron beam lithographer. This causes a chemical change in the PMMA so that when the PMMA is developed, the PMMA on areas that have not been exposed to the electron beam irradiation are removed and areas that have been exposed to the electron beam remain. In this way, a PMMA pattern is produced. The pattern includes selected areas on the ultra-thin graphitic layer that are covered with PMMA and other areas where the PMMA have been removed.

Subjecting the silicon carbide crystal and graphitic layer to an oxygen plasma treatment (e.g., by using the reactive ion etching method) results in ultra-thin graphitic layers that are not covered by the PMMA being consumed by the reactive ions, resulting in a patterned ultra-thin graphitic layer on a silicon carbide crystal. Such patterned ultra-thin graphitic layers have been shown to have beneficial electronic properties.

Unfortunately, it is difficult to make extremely fine ultra-thin graphitic patterns that are required for many functional electronic structures using existing methods. A graphitic ribbon with a width that is less than 20 nm is required to produce a band gap in the graphitic ribbon that is sufficiently large for certain room-temperature electronics applications. Hence, there are many applications that require ultra-thin graphitic ribbons in which the ribbon width is less than 20 nm. Such a width may be difficult to achieve using conventional microelectronics lithography methods. Also, conventional microelectronics patterning methods applied to ultra-thin graphitic layers on silicon carbide involve processes that etch the ultra-thin graphitic layer to produce desired shapes. This etching process may produce patterned ultra-thin graphitic layers with damaged edges, which may interfere with the functionality of the graphitic structures.

Therefore, there is a need for a method for growing ultra-thin graphitic layers only on selected areas of a silicon carbide crystal.

There is also a need for a method for producing graphitic patterns on sidewalls that result from etching a silicon carbide crystal.

There is also a need for a method for producing graphitic patterns on sidewalls that that result from etching a silicon carbide crystal and at the same time to inhibit the growth of an ultra-thin graphitic layer on selected areas substantially horizontal surfaces of the silicon carbide crystal by applying a growth-inhibiting layer on those selected areas.

There is also a need for a method for producing substantially freestanding ultra-thin graphitic patterns on a silicon carbide crystal substrate.

### SUMMARY OF THE INVENTION

The disadvantages of the prior art are overcome by the present invention which, in one aspect, is a method of making a vertical graphitic path on a silicon carbide crystal having a horizontal surface, in which a portion of the silicon carbide crystal is removed from the horizontal surface so as to define a vertical surface that is transverse to the horizontal surface of the silicon carbide crystal. The vertical surface is annealed so as to generate a thin-film graphitic layer on the vertical surface.

In another aspect, the invention is a method of making a graphitic structure, in which a material that inhibits formation of a graphitic layer when the silicon carbide crystal is annealed is applied to a surface of a silicon carbide crystal so as to define at least one opening that exposes a portion of the surface of the silicon carbide crystal. The portion of the silicon carbide crystal is annealed so as to generate a thin-film graphitic layer in the portion of the silicon carbide crystal.

In another aspect, the invention is a method of making a graphitic structure, in which a surface of a silicon carbide crystal is annealed so as to generate a graphitic layer having a first thickness. A layer of a mask material that inhibits generation of graphitic material in silicon carbide is applied to a portion of the graphitic layer. The surface of the silicon carbide crystal is annealed so that the graphic layer becomes thicker than the first thickness except in an area subtended by the mask material.

In another aspect, the invention is a structure that includes a crystalline substrate and a first thin-film graphitic layer. The crystalline substrate includes a horizontal surface and an elongated vertical wall transverse to the horizontal surface. The first thin-film graphitic layer is disposed on the elongated vertical wall.

In yet another aspect, the invention is an active device that includes a silicon carbide crystal, an elongated thin-film graphitic layer, a source electrode, a drain electrode, a dielectric layer and a gate electrode. The silicon carbide crystal has a horizontal surface and a vertical wall transverse to the horizontal surface. The elongated thin-film graphitic layer is disposed on the vertical wall so as to have a first end and a spaced-apart second end. The source electrode is in electrical contact with the first end of the elongated thin-film graphitic layer and the drain electrode is in electrical contact with the second end of the elongated thin-film graphitic layer. The dielectric layer is disposed over a portion of the elongated thin-film graphitic layer. The gate electrode is disposed adjacent to the dielectric layer so as to be insulated from the source electrode, the drain electrode and the elongated thin-film graphitic layer.

These and other aspects of the invention will become apparent from the following description of the preferred embodiments taken in conjunction with the following drawings. As would be obvious to one skilled in the art, many variations and modifications of the invention may be effected without departing from the spirit and scope of the novel concepts of the disclosure.

### BRIEF DESCRIPTION OF THE FIGURES OF THE DRAWINGS

The figures are not necessarily drawn to scale and do not imply relative dimensions or angles of any of the components. Also, straight lines in the figures do not imply any degree of smoothness.

FIGS. 1A-1E are elevational views of a silicon carbide crystal at different stages of graphitization, in which a horizontal graphitic structure is formed.

FIGS. 2A-2D are elevational views of a silicon carbide crystal at different stages of graphitization, in which a vertical graphitic structure is formed.

FIGS. 3A-3D are elevational views of a silicon carbide crystal at different stages of graphitization, in which two vertical graphitic structures are formed.

FIGS. 4A-4E are elevational views of a silicon carbide crystal at different stages of graphitization, in which two vertical graphitic structures are formed.

FIGS. 5A-5B are elevational views of a silicon carbide crystal at different stages of graphitization, in which a graphitic structure is formed.

FIGS. 6A-6E are elevational views of a silicon carbide crystal at different stages of graphitization, in which two vertical graphitic structures are formed in a trench.

FIGS. 7A-7D are elevational views of a silicon carbide crystal at different stages of graphitization, in which two vertical graphitic structures are formed in a trench.

FIGS. 8A-8D are elevational views of a silicon carbide crystal at different stages of graphitization, in which complex graphitic structures are formed in a trench.

FIG. 9A is a plan view of a silicon carbide crystal that includes a first stage of a graphitic structure.

FIG. 9B is a cross-sectional view of the crystal shown in FIG. 9A, taken along line 9A-9A.

FIG. 9C is a plan view of a silicon carbide crystal that includes a second stage of a graphitic structure.

FIG. 9D is a cross-sectional view of the crystal shown in FIG. 9C, taken along line 9D-9D.

FIG. 9E is a plan view of a silicon carbide crystal that includes a third stage of a graphitic structure.

FIG. 9F is a cross-sectional view of the crystal shown in FIGS. 9A-E, in which a multi-level graphitic structure is formed.

FIG. 10A is a plan view of an active device.

FIG. 10B is a perspective view of the active device show in FIG. 10A.

FIG. 10C is a cross-sectional view of the active device show in FIGS. 10A and 10B, taken along line 10C-10C.

FIGS. 11A-11B are plan views of two active devices.

### DETAILED DESCRIPTION OF THE INVENTION

A preferred embodiment of the invention is now described in detail. Referring to the drawings, like numbers indicate like parts throughout the views. As used in the description herein and throughout the claims, the following terms take the meanings explicitly associated herein, unless the context clearly dictates otherwise: the meaning of “a,” “an,” and “the” includes plural reference, the meaning of “in” includes “in” and “on.” As used herein “vertical” refers to any first selected orientation, “horizontal” refers to any second selected orientation that is not parallel to the first selected orientation and “transverse” refers to a relationship between two objects that are at an angle relative to each other that is greater than 0° and less than 180°.

Ultra-thin graphitic layers are grown on a silicon carbide crystal by the high temperature annealing process which causes silicon to evaporate from the silicon carbide surface, which causes the surface of the crystal to become carbon-rich and form into an ultra-thin graphitic layer. Patterning is achieved either by a process in which a mask layer is applied on selected areas of the silicon carbide surface, so that silicon evaporation is inhibited; by a process where the silicon carbide is etched to produce sidewalls which are subsequently graphitized by the high temperature annealing process; or by a combination of these two processes. This may be followed by processes to remove graphitic material from selected areas on the silicon carbide substrate.

Experiments in the laboratory have demonstrated that ultra-thin graphitic layers form on the sidewalls of etched silicon carbide crystals upon being subjected to high temperature annealing. Specifically, in these experiments portions of the surface of a silicon carbide crystal was provided with an aluminum hard mask. The crystal was subsequently subjected to a reactive ion etch using CHF₃ as the etching gas to etch the unprotected silicon carbide crystal to a depth of approximately 100 nm. This technique etched the silicon carbide surfaces that were not protected by the hard mask. The substantially vertical surfaces at the edges of the etched regions are referred to herein as “sidewalls.” When the etched silicon carbide crystal was subjected to the high temperature annealing process not only the horizontal surfaces, but also the sidewall surfaces acquired an ultra-thin graphitic layer. When in the high temperature annealing process, silicon evaporation from the surface of the silicon carbide under the mask was inhibited so that the surface did not become carbon rich and so that the growth rate of the ultra-thin graphitic layer was substantially reduced.

In some applications, the mask material layer includes a material that is not substantially reduced in thickness by the application of a reactive ion etch. In other applications, mask material layer includes two layers: a first layer is a material that can be coated on top of a silicon carbide surface and that substantially reduces the rate of growth of the ultra-thin graphitic layer during annealing; and a second layer on top of the first layer, which has the property that it is not removed by an ion etching procedure, used, for example to etch silicon carbide.

U.S. Pat. Nos. 7,015,142 and 7,327,000 disclose methods of generating a thin-film graphitic layer on a silicon carbide crystal (See, e.g., U.S. Pat. No. 7,015,142, col. 3, 1. 55-col. 4, 1. 65 and col. 5, 1. 62-col. 6, 1. 31). These patents are hereby incorporated by reference in support of the disclosure of methods of making thin-film graphitic layers that follows.

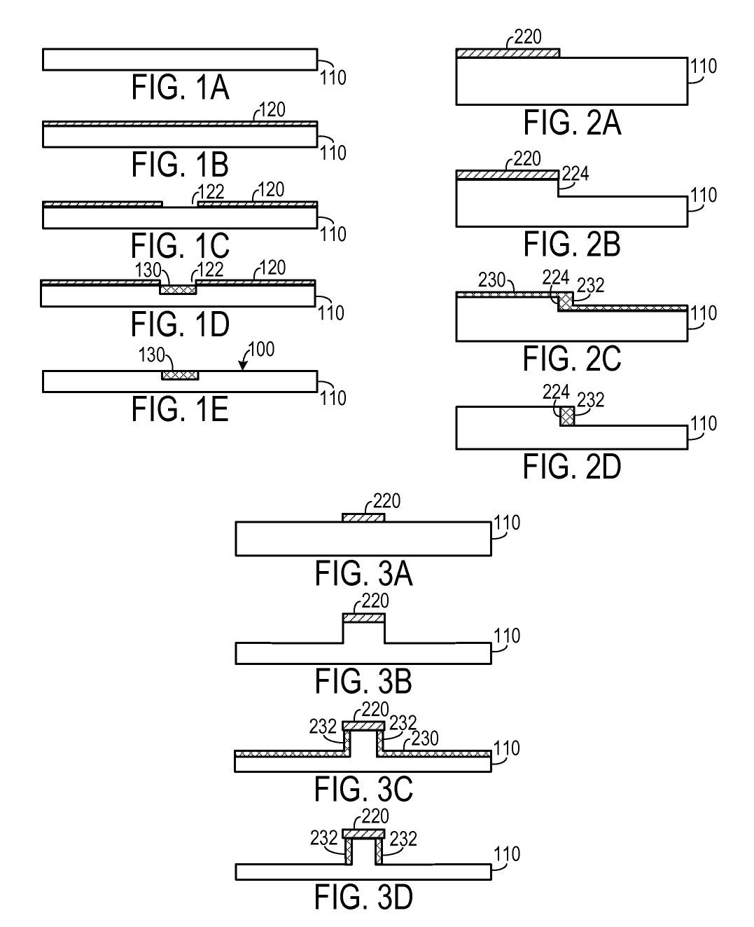

As shown in FIGS. 1A-1E, in one method of generating an ultra-thin film graphitic layer 130, a graphitic layer growth inhibiting mask material layer 120 is applied to a surface of a silicon carbide crystal 110 and an opening 122 is defined in the mask material layer 120. The mask material layer 120 includes a material that substantially reduces the growth rate of an ultra-thin graphitic layer under the mask material layer 120 during a high temperature annealing process. Creation of the opening 122 may be done using well known photo-lithography techniques. The mask material layer 120 has the property that in the high temperature annealing process, it does not completely evaporate from the surface or is not otherwise removed from the surface. In one embodiment, the mask material layer 120 may include a layer of tantalum, tungsten, chromium, aluminum oxide, or boron nitride. In such an embodiment, the mask material layer 120 may be applied to the surface of the silicon carbide crystal 110 with a thickness in a range of 0.5 nm to 1 μm.

At least the area of the opening 122 (and the entire surface of the crystal 110 in most practical applications) is annealed at a temperature and pressure that causes silicon to evaporate from the crystal 110, thereby leaving a horizontal thin graphitic film 130 in the region under the opening 122. The remaining mask material 120 may be removed, thereby leaving a patterned silicon carbide substrate 100.

A method of making a vertical thin film graphitic layer is shown in FIGS. 2A-2D. An etch-resistant mask layer 220 is applied to a portion of a face of a silicon carbide crystal 110 and the exposed surface of the silicon carbide crystal 110 is etched, thereby creating a substantially vertical sidewall 224. In one embodiment, the height of the vertical sidewall 224 is in the range from 0.5 nm to 1 μm. Etching may be accomplished, in one representative example, using a dry etching technique that employs an inductively-coupled plasma (ICP) using sulfur hexafluoride (SF₆) or carbon hydro-trifluoride (CHF₃) as the etching gas.

The etch-resistant mask layer 220 is removed and the crystal 110 is subjected to a high temperature annealing process, thereby producing an ultra-thin graphitic layer 230 on the surfaces of the crystal 110. The ultra-thin graphitic layer 230 includes a vertical ultra-thin graphitic ribbon 232.

The ultra-thin graphitic layer 230 is subjected to a directional reactive ion etch using, for example, a inductively-coupled plasma with oxygen as the reaction gas. This process removes the portion of the graphitic layer 230 on the horizontal surfaces and leaves the graphitic material only on the vertical surfaces, leaving the ultra-thin graphitic ribbon 232 on the etched sidewall 224.

This method may be used to make two parallel vertical ultra-thin graphitic ribbons 232, as shown in FIGS. 3A-3D. A strip of an etch-resistant mask material 220 along a surface of the silicon carbide crystal 110. The crystal 110 is etched, as described above, and the crystal 110 is annealed, thereby forming two parallel vertical ultra-thin graphitic ribbons 2320 on the exposed portions of the crystal 110. The remaining mask material 220 may be left on the crystal 110 or removed using a solvent, depending on the application.

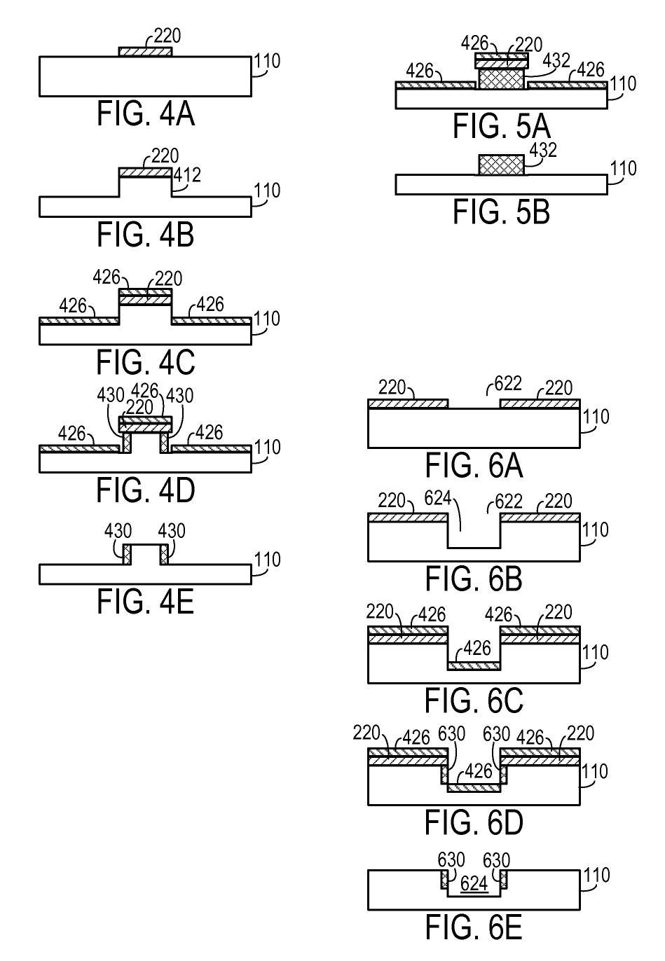

FIGS. 4A-4E show an alternate method of making two parallel vertical ultra-thin graphitic ribbons 430, in which a strip of an etch-resistant mask material 220 is applied along a surface of the silicon carbide crystal 110. The crystal 110 is etched, as described above, to create a raised pattern 412 and a graphitic growth inhibiting mask material 426 (such as PMMA) is applied to the horizontal surfaces. The crystal 110 is annealed, thereby forming two parallel vertical ultra-thin graphitic ribbons 430 on the exposed portions of the crystal 110. Again, depending on the application, the remaining mask layer may be removed. A plasma etch using, for example, the ICP method with oxygen gas may be applied to remove residual graphitic material that may have formed under the growth inhibiting mask material 426.

As shown in FIGS. 5A-5B, if the crystal 110 shown in FIGS. 4A-4E is annealed long enough, the graphitic ribbons converge on each other, so that the raised pattern is completely converted to an ultra-thin graphitic layer, which now forms a structure 432 including graphene sheets that are transverse to the silicon carbide crystal surface.

As shown in FIGS. 6A-6E, an etch-resistant etch layer 220 defining at least one opening 622 therethrough is applied to the crystal 110 and the crystal is subjected to a etching process (as described above) to form a trench 624, which in one example may be 0.5 nm to several millimeters wide and 0.5 nm to 1 μm deep. A layer of graphitic growth inhibiting mask material 426 is applied to the horizontal surfaces and the crystal is annealed to form ultra-thin graphitic layers 630 on the sidewalls of the trench 624.

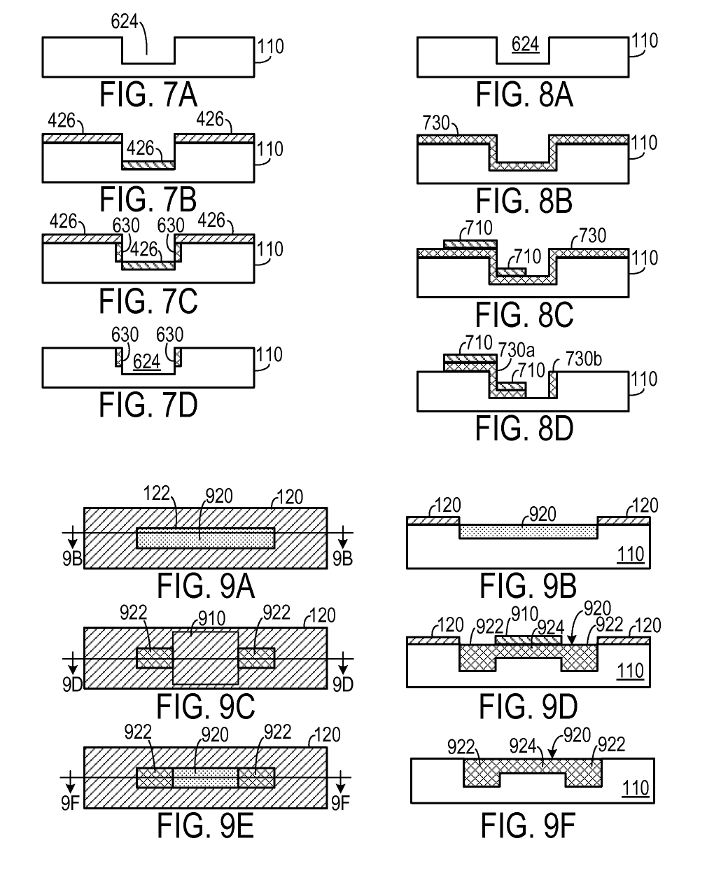

As shown in FIGS. 7A-7D, a mask-less etching process may be employed to form the trench 624. In one example, a focused ion beam may be used to form the trench 624.

As shown in FIGS. 8A-8D, a more complex structure may be made by employing the methods disclosed above. For example, after the trench 624 is etched into the crystal 110, the crystal is annealed to create an ultra-thin graphitic layer on both the horizontal surfaces and the vertical surfaces of the crystal 110. An etch-resistant mask material 710 is applied to selected portions of the horizontal surfaces and the crystal 110 is subjected to a directional etch. This leaves two separate ultra-thin film graphitic structures: a first structure 730a that includes both a vertical wall and two horizontal ribbons extending from the vertical side wall; and a second structure 730b that includes the opposite vertical side wall.

The making of a graphitic structure of multiple depths is shown in FIGS. 9A-9F using a method similar to the method disclosed with reference to FIGS. 1A-1E. The graphitic growth inhibiting mask material 120 is applied to the crystal so as to define an opening 122 therethrough and the crystal 110 is annealed to create a first portion 924 of a graphitic structure 920 having a first depth. A second layer 910 of the graphitic growth inhibiting mask material 120 is then applied to an exposed portion of the graphitic structure 920 and the crystal 110 is annealed again so as to form a second, deeper, portion 922 of the graphitic structure 920. This embodiment can be used, for example, to produce field effect transistors in which the narrow first portion 924 of the structure 920 forms a channel, and the wider second portions 922 form a source and a drain of a field effect transistor.

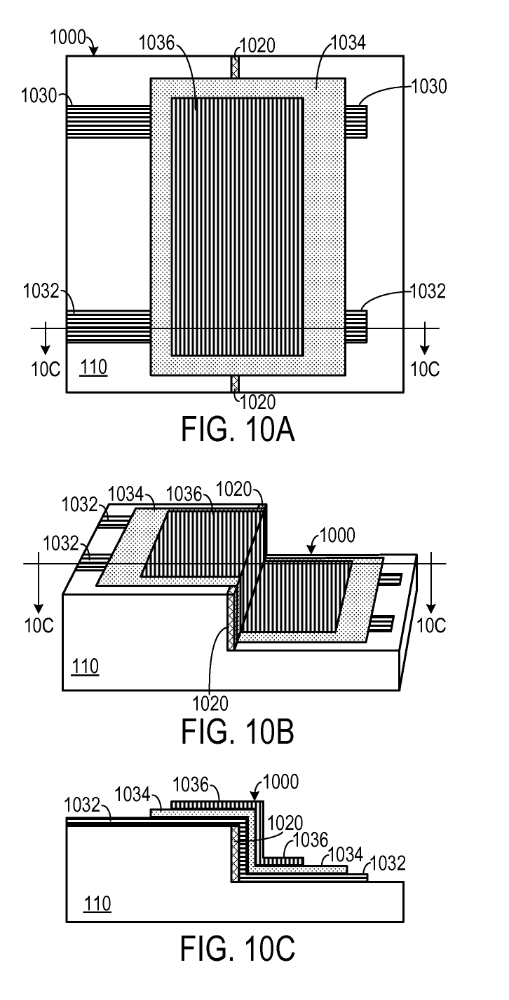

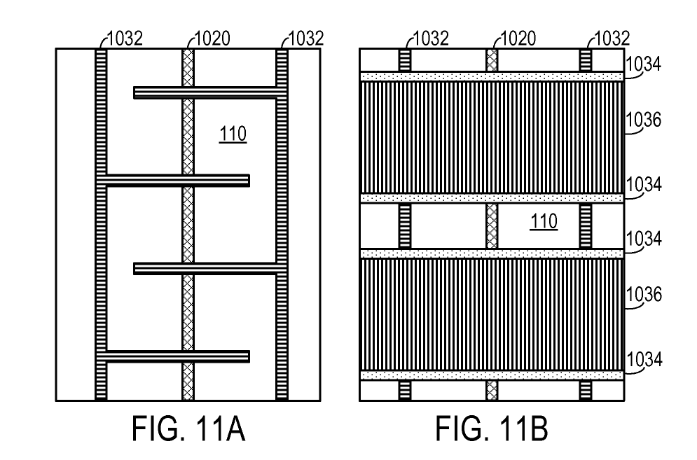

One example of a field effect transistor 1000 employing an ultra-thin film graphitic ribbon 1020 is shown in FIGS. 10A-10C. Once the ultra-thin film graphitic ribbon 1020 is formed in the crystal 110 using methods such as those described above, two spaced apart electrodes 1032 are deposited a strips transverse to the ultra-thin film graphitic ribbon 1020. These electrodes 1032 (which could include a metal, e.g., evaporated palladium strips) act as a source and a drain. An dielectric layer 1034 (such as a 10 nm thick hafnia layer) is applied over the electrodes 1032 and a conductive layer 1036, such as a metal layer, is applied to the dielectric layer 1034 so as to be electrically isolated from the electrodes 1032 and the ultra-thin film graphitic ribbon 1020 (which acts as a channel). The conductive layer 1036 (which could include a 10 nm thick gold layer) acts as a gate. A multi-transistor structure of this type is shown in FIGS. 11A-11B.

The above described embodiments, while including the preferred embodiment and the best mode of the invention known to the inventor at the time of filing, are given as illustrative examples only. It will be readily appreciated that many deviations may be made from the specific embodiments disclosed in this specification without departing from the spirit and scope of the invention. Accordingly, the scope of the invention is to be determined by the claims below rather than being limited to the specifically described embodiments above.

1. A method of making a vertical graphitic path on a silicon carbide crystal having a horizontal surface, comprising the actions of:
a. removing a portion of the silicon carbide crystal from the horizontal surface so as to define a vertical surface that is transverse to the horizontal surface of the silicon carbide crystal; and
b. annealing the vertical surface so as to generate a thin-film graphitic layer on the vertical surface.

2. The method of claim 1, wherein the removing a selected portion of the silicon carbide crystal action comprises the actions of:
a. applying an etch mask material to the silicon carbide crystal so as to define an opening exposing a first portion of the silicon carbide crystal; and
b. etching the first portion of the silicon carbide material exposed through the opening.

3. The method of claim 2, wherein the etching action comprises subjecting the opening to a reactive ion etch.

4. The method of claim 3, wherein the reactive ion etch comprises CHF₃.

5. The method of claim 1, wherein the annealing action results in a thin-film graphitic layer forming on a first horizontal portion of the horizontal surface.

6. The method of claim 5, further comprising the action of removing a second horizontal portion of the thin-film graphitic layer from the horizontal surface.

7. The method of claim 6, wherein the action of removing the second horizontal portion of the thin-film graphitic layer from the horizontal surface comprises the action of subjecting the second horizontal portion to a directional ion etch.

8. The method of claim 7, wherein the directional ion etch comprises an inductively-coupled plasma employing oxygen as a reactive gas.

9. The method of claim 7, further comprising the actions of applying a second masking material, that resists the directional ion etch, so that the second masking material exposes the third portion of the thin-film graphitic layer.

10. The method of claim 5, further comprising the action of applying a graphitic layer growth inhibiting mask material to selected portions of the silicon carbide crystal prior to the annealing action so as to inhibit growth of the thin-film graphitic layer in the selected portions of the silicon carbide crystal.

11. The method of claim 1, further comprising the action of applying a first conductive material to a section of the silicon carbide crystal so as to be in electrical contact with the thin-film graphitic layer.

12. The method of claim 11, therein the first conductive material comprises a metal.

13. The method of claim 11, further comprising the action of applying a dielectric material to a selected portion of first conductive material.

14. The method of claim 13, further comprising the action of applying a second conductive material to the dielectric material so as to form a field effect node.

15. The method of claim 1, wherein the annealing action comprises the step of heating the vertical surface to a selected temperature at a selected pressure and for a selected amount of time sufficient so that the thin-film graphitic layer forms on the vertical surface.

16. The method of claim 15, wherein the selected temperature is greater than 1500° C.

17. The method of claim 15, wherein the selected pressure is below 10⁻⁴ Torr.

18. The method of claim 15, wherein the selected amount of time is substantially 20 minutes.

19. A method of making a graphitic structure, comprising the actions of:
a. applying, to a surface of a silicon carbide crystal, a material that inhibits formation of a graphitic layer when the silicon carbide crystal is annealed so as to define at least one opening that exposes a portion of the surface of the silicon carbide crystal; and
b. annealing the portion of the silicon carbide crystal so as to generate a thin-film graphitic layer in the portion of the silicon carbide crystal.

20. A method of making a graphitic structure, comprising the actions of:
a. annealing a surface of a silicon carbide crystal so as to generate a graphitic layer having a first thickness;
b. applying, to a portion of the graphitic layer, a layer of a mask material that inhibits generation of graphitic material in silicon carbide; and
c. annealing the surface of the silicon carbide crystal so that the graphie graphitic layer becomes thicker than the first thickness except in an area subtended by the mask material.

21. A structure, comprising:
a. a crystalline substrate that includes a horizontal surface and an elongated vertical wall transverse to the horizontal surface; and
b. a first thin-film graphitic layer disposed on the elongated vertical wall.

22. The structure of claim 21, further comprising a conductive material that is in electrical communication with the first thin-film graphitic layer.

23. The structure of claim 21, further comprising a second thin-film graphitic layer disposed on a portion of the horizontal surface.

24. The structure of claim 23, further comprising a conductive material that is in electrical communication with the first thin-film graphitic layer.

25. The structure of claim 23, further comprising a dielectric layer applied thereto.

26. The structure of claim 25, wherein the dielectric layer comprises hafnium oxide.

27. An active device, comprising:
a. a silicon carbide crystal having a horizontal surface and a vertical wall transverse to the horizontal surface;
b. an elongated thin-film graphitic layer disposed on the vertical wall so as to have a first end and a spaced-apart second end;
c. a source electrode in electrical contact with the first end of the elongated thin-film graphitic layer and a drain electrode in electrical contact with the second end of the elongated thin-film graphitic layer;
d. a dielectric layer disposed over a portion of the elongated thin-film graphitic layer; and
e. a gate electrode disposed adjacent to the dielectric layer so as to be insulated from the source electrode, the drain electrode and the elongated thin-film graphitic layer.
